(19) United States
(12) Patent Application Publication
(10) Pub. No.: US 2014/0104791 A1
(43) Pub. Date: Apr. 17, 2014

(54) MOUNTING APPARATUS FOR BRACKET OF HEAT SINK

(71) Applicants: HON HAI PRECISION INDUSTRY CO., LTD., New Taipei (TW); HONG FU JIN PRECISION INDUSTRY (ShenZhen) Co., Ltd, Shenzhen (CN)

(72) Inventors: CHIH-HAO YANG, New Taipei (TW); XIANG-KUN ZENG, Shenzhen (CN); RONG YANG, Shenzhen (CN); CHENG HAO, Shenzhen (CN)

(21) Appl. No.: 13/930,163

(22) Filed: Jun. 28, 2013

(30) Foreign Application Priority Data
Oct. 16, 2012 (CN) 2012103918196

(51) Int. Cl. H05K 1/02

(52) U.S. Cl. CPC H05K 1/021; H05K 1/0203
USPC 361/720

(57) ABSTRACT

A circuit board assembly includes a circuit board and a bracket of a heat sink. The bracket of the heat sink includes a pair of first securing feet and a pair of second securing feet opposite to the pair of first securing feet. A pair of first securing members is secured to the circuit board. A pair of second securing members is secured to the circuit board facing the pair of first securing members. The pair of first securing members includes a pair of elastic pieces which faces the pair of second securing members. The pair of first securing feet abuts against the pair of elastic pieces to elastically deform the pair of elastic pieces. The pair of elastic pieces exerts force on the bracket to push the pair of second securing feet to abut against the pair of second securing members.

### BACKGROUND

1. Technical Field

The present disclosure relates to a mounting apparatus for mounting a bracket of a heat sink.

2. Description of Related Art

Heat sinks are typically mounted on electronic components (such as chipsets) by a bracket to dissipate heat. The bracket is usually fixedly mounted on a printed circuit board, on which the electronic components are attached. When the printed circuit board needs to be maintained, it is inconvenient to detach the bracket.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus for mounting a bracket on a circuit board.

FIG. 2 is similar to FIG. 1, but viewed from another aspect.

FIG. 3 is an exploded, isometric view of a first securing member and an elastic piece of the mounting apparatus of FIG. 1.

FIG. 4 is a cross-sectional view of the mounting apparatus of FIG. 1.

FIG. 5 is an assembled view of the mounting apparatus of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

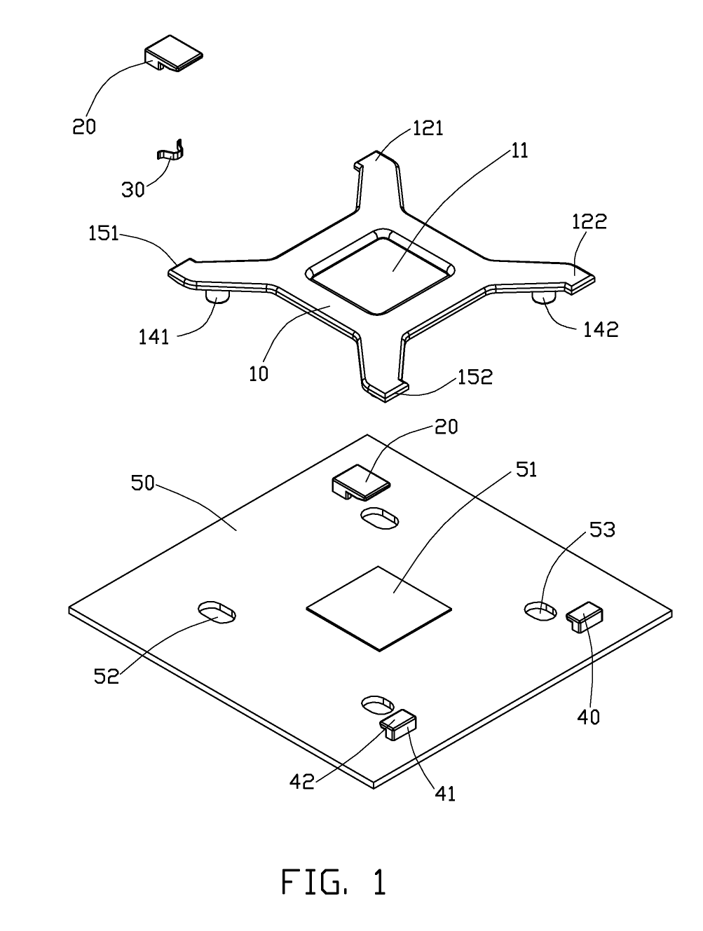

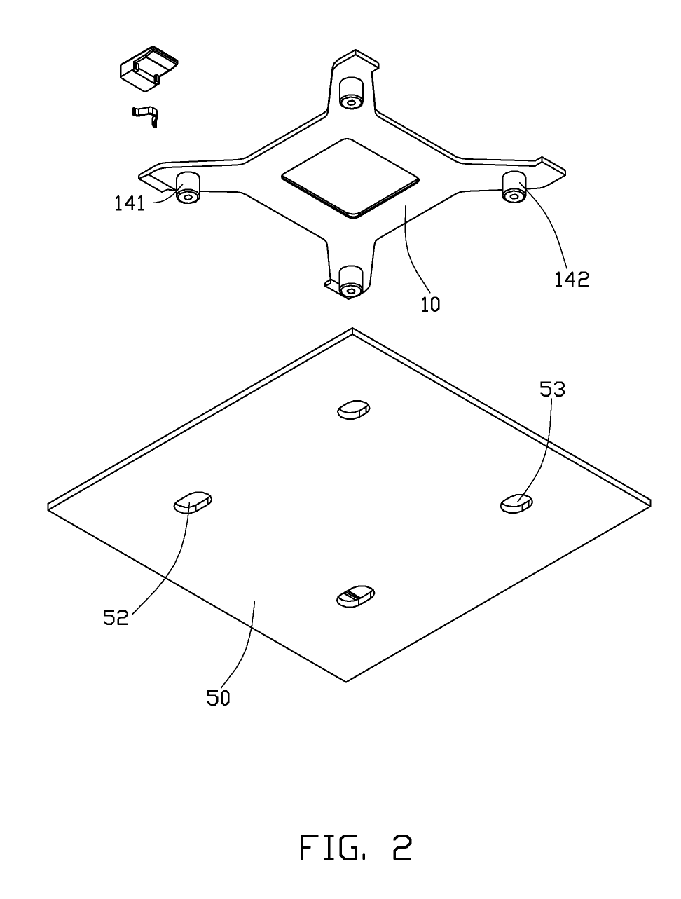

FIGS. 1 and 2 show an embodiment of a mounting apparatus for mounting a bracket 10 on a circuit board 50. The mounting apparatus includes a pair of first securing members 20, a pair of elastic pieces 30, and a pair of second securing members 40.

A chipset 51 is mounted on the circuit board 50. The circuit board 50 defines a pair of first sliding grooves 52 adjacent to a first side of the chipset 51. The circuit board 50 further defines a pair of second sliding grooves 53 adjacent to a second side of the chipset 51 opposite to the first side.

A center portion of the bracket 10 defines an opening 11 corresponding to the chipset 51. The chipset 51 contacts a heat sink (not shown) via the opening 11. The bracket 10 includes a pair of first securing feet 121 on one side and a pair of second securing feet 122 on another side opposite to the pair of first securing feet 121. Each of the first securing feet 121 includes a first post 141 extending down. Each of the second securing feet 122 includes a second post 142 extending down. A distal end of each of the first securing foot 121 includes a first resisting end 151. A distal end of each of the second securing foot 122 includes a second resisting end 152.

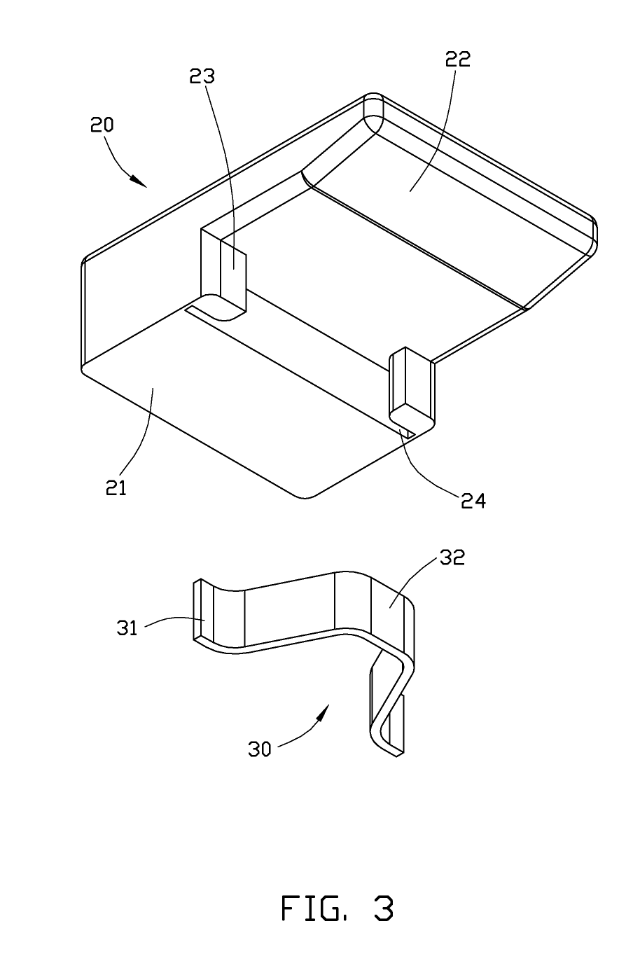

Referring to FIG. 3, each of the first securing member 20 includes a first mounting base 21. A top portion of the first mounting base 21 extends horizontally to form a first restricting piece 22. A pair of restricting tabs 23 is connected to the first mounting base 21 and located below the first restricting piece 22. The restricting tab 23 is “L” shaped and a slit 24 is defined between the restricting tab 23 and the first mounting base 21.

The elastic pieces 30 can be elastically deformed. A center portion of the elastic piece 30 is an abutting portion 32, and on opposite ends of the elastic piece 30 is a pair of securing portions 31. The abutting portion 32 extends out from the securing portions 31.

Referring to FIG. 1, each of the second securing member 40 includes a second mounting base 41. A top portion of the second mounting base extends horizontally to form a second restricting piece 42.

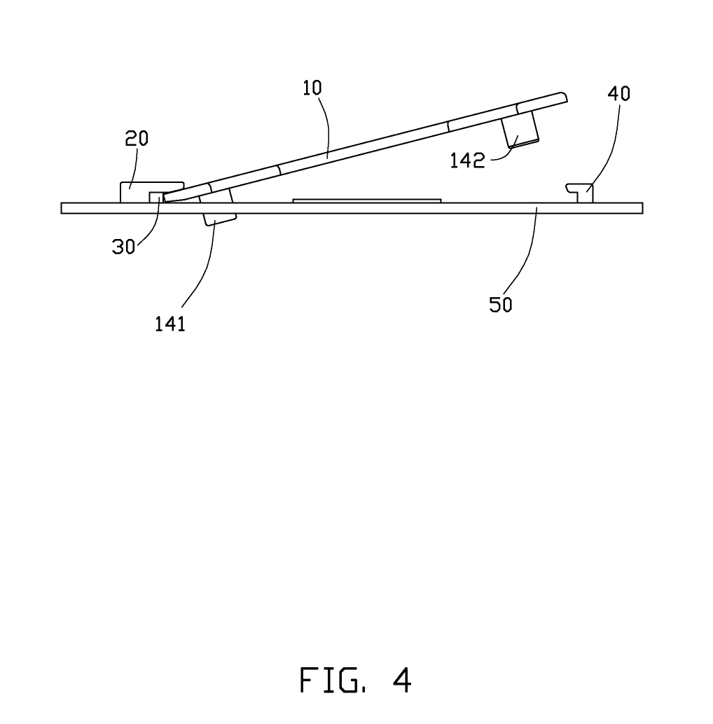

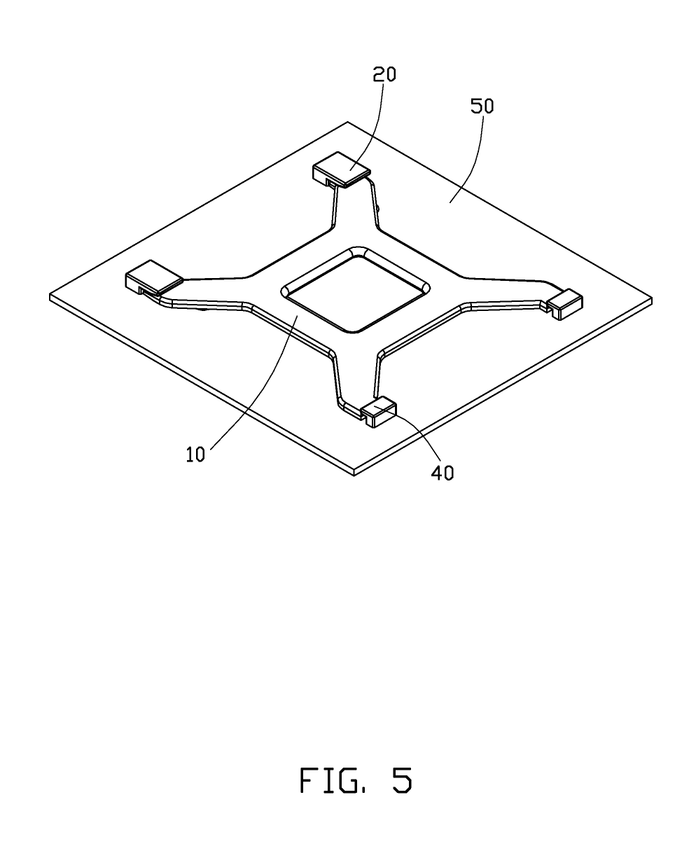

Referring to FIGS. 1 to 5, in assembly, the elastic piece 30 is mounted on the first securing member 20 by elastically deforming the pair of securing portions 31 to insert into the slits 24 of the first securing member 20. The first mounting bases 21 of the pair of first securing members 20 are attached on the circuit board 50 by conventional means. The pair of first securing members 20 is aligned with the pair of first sliding grooves 52. The distal edge of the first restricting pieces 22 align with a distal edge of the first sliding grooves 52. The second mounting bases 41 of the pair of second securing members 40 are attached to the circuit board 50 by conventional means. The pair of second securing members 40 is aligned with the pair of second sliding grooves 53. A distal edge of the second restricting pieces 42 align with a distal edge of the second sliding grooves 53.

The first posts 141 on the pair of first securing feet 121 are inserted and slide into the first sliding grooves 52 of the circuit board 50 so that the first resisting ends 151 are located below the first restricting pieces 22 and abut against the abutting portions 32 of the pair of elastic pieces 30. This elastically deforms the elastic pieces 30. In this position, the second posts 142 on the pair of second securing feet 122 are inserted and slide into the second sliding grooves 53 so that the second resisting ends 152 are below the second restricting pieces 42. When the bracket 10 is released, the elastic pieces 30 elastically push the bracket 10 so that the second resisting ends 152 abut against the second mounting bases 41. Thereby, the bracket 10 is mounted on the circuit board 50.

The bracket 10 is detached from the circuit board 50 by moving the bracket 10 against the abutting portions 32 of the pair of elastic pieces 30 so that the second resisting ends 152 slide out of the second securing members 40. Thus, the bracket 10 is easily removed from the circuit board 50.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A circuit board assembly, comprising:
a circuit board;
a bracket configured to accommodate a heat sink, the bracket comprising a pair of first securing feet and a pair of second securing feet opposite to the pair of first securing feet; and
a pair of first securing members and a pair of second securing members secured to the circuit board, each of a pair of elastic pieces attached to each of the pair of first securing members;
wherein each of the pair of first securing feet abuts each of the pair of elastic pieces, the pair of elastic pieces are elastically deformed to exert force on the bracket and to push the pair of second securing feet to abut on the pair of second securing members.

2. The circuit board assembly of claim 1, wherein each of the pair of first securing members comprises a first mounting base secured to the circuit board and a first restricting piece extending from a top portion of the first mounting base, the pair of first securing feet are located between the first restricting pieces of the pair of first securing members and the circuit board, and the first restricting pieces of the pair of first securing members restrict the pair of first securing feet on the circuit board.

3. The circuit board assembly of claim 2, wherein each of the pair of first securing members comprises a pair of restricting tabs, each of the pair of restricting tabs is located below the first restricting piece relative to the first mounting base, a pair of slits are defined between the pair of restricting tabs and the first mounting base, each of the pair of the elastic pieces comprises a pair of securing portions, and each of the pair of securing portions is inserted into each of the pair of slits to mount the elastic piece on the first securing member.

4. The circuit board assembly of claim 3, wherein each of the pair of the elastic pieces comprises an abutting portion, the abutting portion is located between the pair of securing portions, and the abutting portion extends out of the pair of securing portions.

5. The circuit board assembly of claim 1, wherein each of the pair of second securing members comprises a second mounting base secured to the circuit board and a second restricting piece extending from a top portion of the second mounting base, the pair of second securing feet are located below the second restricting pieces of the pair of second securing members relative to the second mounting base, and the first restricting pieces of the pair of first securing members restrict the pair of first securing feet on the circuit board.

6. The circuit board assembly of claim 1, wherein the pair of first securing feet comprises a pair of first posts extending from the pair of first securing feet, the circuit board defines a pair of first sliding grooves, and each of the pair of first posts is inserted into each of the pair of first sliding grooves and is slidable in the pair of first sliding grooves.

7. The circuit board assembly of claim 6, wherein the pair of second securing feet comprises a pair of second posts extending from the pair of second securing feet, the circuit board defines a pair of second sliding grooves, and each of the pair of second posts is inserted into each of the pair of second sliding grooves and is slidable in the pair of second sliding grooves.

8. The circuit board assembly of claim 6, wherein the pair of first sliding grooves and the pair of second sliding grooves are configured to hold opposite edges of a chipset.

9. The circuit board assembly of claim 7, wherein the bracket defines an opening among the pair of first securing feet and the pair of second securing feet, and the opening is configure to received the chipset therein.

10. A circuit board assembly, comprising:
a circuit board configured to attached a chipset thereon;
a bracket comprising a pair of first securing feet on one side and a pair of second securing feet on another side opposite to the pair of first securing feet, the bracket defining an opening among the pair of first securing feet and the pair of second securing feet; and
a pair of first securing members secured to the circuit board and adjacent to a first edge of the chipset, a pair of second securing members secured to the circuit board and adjacent to a second edge of the chipset, the second edge being opposite to the first edge, the pair of first securing members comprising a pair of elastic pieces facing the chipset;
wherein each of the pair of first securing feet abuts each of the pair of elastic pieces, each of the pair of elastic pieces is elastically deformed to push the bracket so that each of the pair of second securing feet abuts each of the pair of second securing members.

11. The circuit board assembly of claim 10, wherein each of the pair of first securing members comprises a first mounting base secured to the circuit board and a first restricting piece extending from a top portion of the first mounting base, the pair of first securing feet are located below the first restricting pieces of the pair of first securing members relative to the first mounting base, and the first restricting pieces of the pair of first securing members restrict the pair of first securing feet on the circuit board.

12. The circuit board assembly of claim 11, wherein each of the pair of first securing members comprises a pair of restricting tabs, each of the restricting tabs is located below each of the first restricting piece relative to the first mounting base, a pair of slits are defined between the pair of restricting tabs and the first mounting base, each of the pair of the elastic pieces comprises a pair of securing portions, and each of the pair of securing portions is inserted into each of the pair of slits to mount the elastic piece on the first securing member.

13. The circuit board assembly of claim 12, wherein each of the pair of elastic pieces comprises an abutting portion, the abutting portions is located between the pair of securing portions, and the abutting portion extends out of the pair of securing portions.

14. The circuit board assembly of claim 10, wherein each of the pair of second securing members comprises a second mounting base secured to the circuit board and a second restricting piece extending from a top portion of the second mounting base, the pair of second securing feet are located below the second restricting pieces of the pair of second securing members relative to the second mounting base, and the first restricting pieces of the pair of first securing members restrict the pair of first securing feet on the circuit board.

15. The circuit board assembly of claim 10, wherein the pair of first securing feet comprises a pair of first posts extending from the pair of first securing feet, the circuit board defines a pair of first sliding grooves, and each of the pair of first posts is inserted into each of the pair of first sliding grooves and is slidable in the pair of first sliding grooves.

16. The circuit board assembly of claim 15, wherein the pair of second securing feet comprises a pair of second posts extending from the pair of second securing feet, the circuit board defines a pair of second sliding grooves, and each of the pair of second posts is inserted into each of the pair of second sliding grooves and is slidable in the pair of second sliding grooves.
